(19) United States
(12) Patent Application Publication
(10) Pub. No.: US 2026/0179665 A1
(43) Pub. Date: Jun. 25, 2026

(54) System with Memory Device Replica for Stable Read Operations

(71) Applicant: Taiwan Semiconductor Manufacturing Company, Ltd., Hsinchu (TW)

(72) Inventors: Yu-Cheng Lin, Hsinchu (TW); Yu-Der Chih, Hsinchu (TW); Chien-Fan Wang, Hsinchu (TW); Yao Xiang Fan, Hsinchu (TW)

(21) Appl. No.: 19/180,380

(22) Filed: Apr. 16, 2025

Related U.S. Application Data
(60) Provisional application No. 63/737,831, filed on Dec. 23, 2024.

(51) Int. Cl. G11C 7/20

(52) U.S. Cl. CPC G11C 7/20

(57) ABSTRACT

A system includes a memory device and a memory replica. The memory device includes a plurality of memory cell, an input-output multiplexer, an input-output sense amplifier, and a storage element. The input-output multiplexer selects one of the memory cells in response to a select signal. The input-output sense amplifier generates a data output signal representing a bit stored in the selected one of the memory cells. The storage element latches the data output signal in response to a data latch signal and outputs a bit that corresponds to the data output signal. The memory device replica mimics the behavior of the memory device and generates the data latch signal.

### CROSS-REFERENCE TO RELATED APPLICATION

The present application claims priority to U.S. Provisional Application No. 63/737,831, filed Dec. 23, 2024, the contents of which are incorporated by reference herein in their entirety.

### BACKGROUND

A memory device stores and retrieves data in a system, e.g., integrated circuit (IC). It can be volatile, like a dynamic random-access memory (DRAM) device and a static random-access memory (SRAM) device, or non-volatile, like a one-time programmable (OTP) memory device. A memory device may include a plurality of memory cells arranged in an array of rows and columns, which store data as electrical charges or resistance states. Address decoders may select one or more of the memory cells at a time for reading or writing operations. For data retrieval, the memory device may rely on peripheral circuits such as sense amplifiers. A sense amplifier may detect and amplify the small voltage or current differences representing the stored data, enabling reliable data access from memory cells.

### BRIEF DESCRIPTION OF THE DRAWINGS

Aspects of the present disclosure are best understood from the following detailed description when read with the accompanying figures:

FIG. 1 is a schematic block diagram illustrating an exemplary system in accordance with various embodiments of the present disclosure;

FIG. 2 is a schematic block/circuit diagram illustrating another exemplary system 200 in accordance with various embodiments of the present disclosure;

FIG. 3 is a schematic block/circuit diagram illustrating another exemplary system in accordance with various embodiments of the present disclosure;

FIG. 4 is a schematic block/circuit diagram illustrating another exemplary system in accordance with various embodiments of the present disclosure;

FIG. 5 is a schematic timing diagram illustrating an exemplary sensing margin window of a system in accordance with various embodiments of the present disclosure;

FIG. 6 is a schematic block/circuit diagram illustrating another exemplary system in accordance with various embodiments of the present disclosure;

FIG. 7 is a schematic block/circuit diagram illustrating another exemplary system in accordance with various embodiments of the present disclosure;

FIG. 8 s a schematic block/circuit diagram illustrating another exemplary system in accordance with various embodiments of the present disclosure;

FIG. 9 is a schematic block/circuit diagram illustrating another exemplary system in accordance with various embodiments of the present disclosure; and

FIG. 10 is a flowchart of an exemplary method of performing a read operation on a memory device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

A sense amplifier, e.g., a differential sense amplifier or a single-ended sense amplifier, detects and amplifies small differences in signals, such as voltage or current, from memory cells to determine stored data. A differential sense amplifier can be configured to read stored data by comparing two signals, e.g., a reference signal and a data signal. While this scheme may improve noise immunity and reliability, it may consume more power compared to a single-ended approach and have a larger circuit area. In contrast, a single-ended sense amplifier may read data by comparing the signal from a memory cell against a reference level. This approach can offer lower power consumption, a smaller circuit area, and a simpler design. However, such a single-ended sense amplifier may require a current mirror to generate a stable and accurate reference current, which can be difficult due to process, voltage, or temperature (PVT) variations.

To address these drawbacks, certain systems and methods as described herein comprises a memory device and a memory device replica that mimics the behavior of the memory device. This approach may, in some instances, eliminate the need for a current mirror in a single-ended sense amplifier of the memory device. In at least one embodiment, the memory device replica enables timing coordination between a pre-charge signal, which initializes the single-ended sense amplifier, and a data latch signal, which captures (or latches) and outputs a data output signal from the single-ended sense amplifier, in a manner that will be described hereinafter.

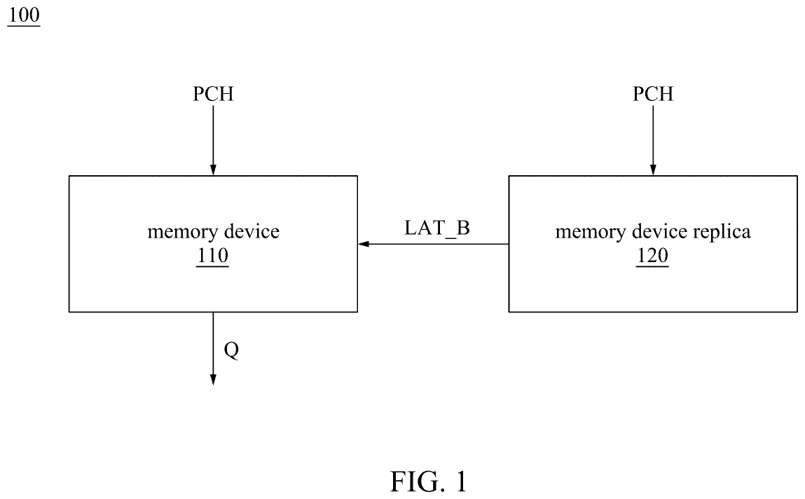

FIG. 1 is a schematic block diagram illustrating an exemplary system 100 in accordance with various embodiments of the present disclosure. As illustrated in FIG. 1, the example system 100 includes a memory device 110 and a memory device replica 120. The memory device 110 stores data therein during write operations and allows the stored data to be retrieved therefrom when a read operation is performed thereon. In a read operation, the memory device 110 is initialized, e.g., to a VDD level, by a pre-charge signal (PCH) (e.g., from a signal generator). In response to a latch signal (LAT_B), the memory device 110 captures (or latches) and outputs a bit (Q) that corresponds to a bit stored in a memory cell thereof.

The memory device replica 120 mimics the behavior of the memory device 110 without storing actual data. For example, during read operations, the memory device replica 120 generates the data latch signal (LAT_B) based on the pre-charge signal (PCH), which initializes the memory device replica 110, e.g., to a VDD level. The memory device replica 120 replicates substantially the same electrical characteristics (e.g., loading effects, leakage conditions, parasitic capacitances, charge/discharge behavior, and signal propagation delays) as the memory device 110. This mimicry ensures timing synchronization, enabling the memory device 110 to correctly output the stored bit (Q).

From the above description, during a read operation, both the memory device 110 and the memory device replica 120 are initialized by a pre-charge signal (PCH). The memory device replica 120 then generates a data latch signal (LAT_B), while the memory device 110, in response the data latch signal (LAT_B), captures (or latches) and outputs a bit (Q) that corresponds to a bit stored in a memory cell thereof. The construction as such eliminates the need for a reference current from a current mirror. Furthermore, because the latch signal (LAT_B) is timing-based rather than current-based, the system 100 minimizes sensitivity to, or does not suffer from, PVT variations, achieving more stable read operations.

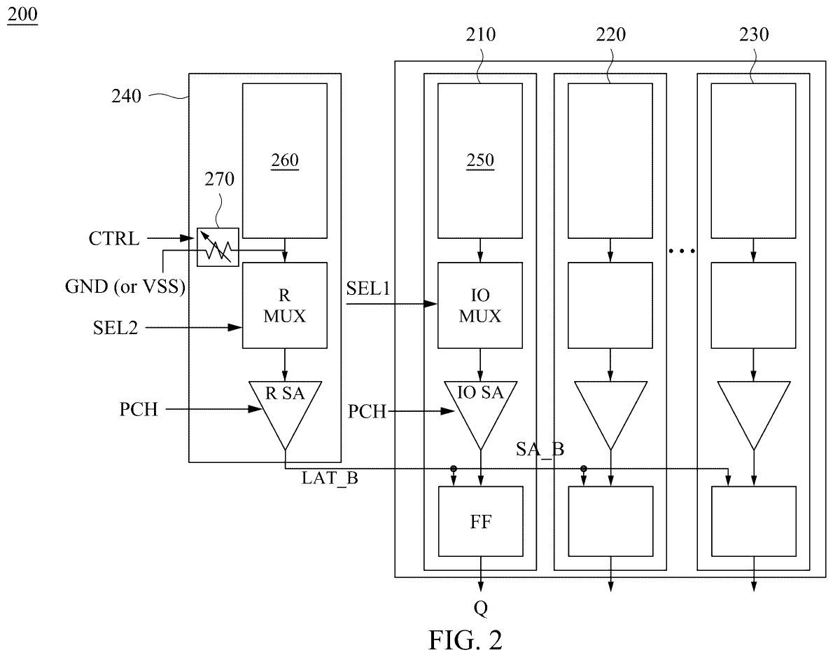

FIG. 2 is a schematic block/circuit diagram illustrating another exemplary system 200 in accordance with various embodiments of the present disclosure. As illustrated in FIG. 2, the example system 200 (e.g., system 100) includes one or more memory devices, e.g., memory devices 210-230, and a memory device replica 240. Because the memory devices 210-230 are similar in structure and functionality, only the memory device 210 will be described in detail. The memory device 210 includes a plurality of memory cells 250, an input-output multiplexer (IO MUX), an input-output sense amplifier (IO SA), and a storage element (FF). The memory cells 250 store data therein during write operations and allow the stored data to be retrieved therefrom when a read operation is performed thereon. The input-output multiplexer (IO MUX) selects one of the memory cells 250 in response to a select signal (SEL1) (e.g., from an address decoder) and connects the selected one of the memory cells 250 to the input-output sense amplifier (IO SA). In at least one embodiment, the input-output sense amplifier (IO SA) is a single-ended sense amplifier.

During read operations, the input-output sense amplifier (IO SA) is initialized, e.g., to a VDD level, by a pre-charge signal (PCH) (e.g., from a signal generator) and generates a data output signal (SA_B) representing the bit stored in the selected one of the memory cells 250. The storage element (FF) receives the data output signal (SA_B) at its data input terminal and, in response to a data latch signal (LAT_B) (e.g., from the memory device replica 240) at its clock input terminal, captures and outputs a bit (Q) that corresponds to the data output signal (SA_B) received thereby. In certain embodiments, the storage element (FF) includes a flip-flop (e.g., D-, JK-, SR-, T-type), a shift register, another type of latch, or a combination thereof.

The memory device replica 240 mimics the behavior of the memory device 250 without storing actual data. For example, the memory device replica 240 includes a plurality of reference cells 260, a reference multiplexer (R MUX), a resistive element 270, and a reference sense amplifier (R SA). The reference multiplexer (R MUX) selects one of the reference cells 260 in response to a select signal (SEL2) (e.g., from an address decoder) and connects the selected one of the reference cells 260 to the reference sense amplifier (R SA). During read operations, the reference sense amplifier (R SA) is initialized, e.g., to a VDD level, by the pre-charge signal (PCH) and generates a data latch signal (LAT_B). The resistive element 270 is connected between the junction of the reference cells 260 and the reference multiplexer (R MUX) and a ground (or VSS) node. In this exemplary embodiment, the resistive element 270 includes a potentiometer and receives a control signal (CTRL) (e.g., from a signal generator) that adjusts its resistance at a predetermined value. In an alternative embodiment, the resistive element 270 includes a resistor that has a fixed resistance value.

In an exemplary read operation, each multiplexer (IO MUX, R-MUX) receives a respective select signal (SEL1, SEL2), establishing connections between a selected one of the memory cells 250 and the input-output sense amplifier (IO SA) and between a selected one of the reference cells 260 and the reference sense amplifier (R SA). Each sense amplifier (IO SA, R SA) is then initialized, e.g., to a VDD level, by a pre-charge signal (PCH) (e.g., from a signal generator). Next, each sense amplifier (IO SA, R SA) generates a respective signal (SA_B, LAT_B). Thereafter, the storage element (FF) receives the data output signal (SA_B) at its data input terminal and, in response to the data latch signal (LAT_B) at a clock input terminal thereof, captures and outputs a bit (Q) that corresponds to the data output signal (SA_B) received thereby.

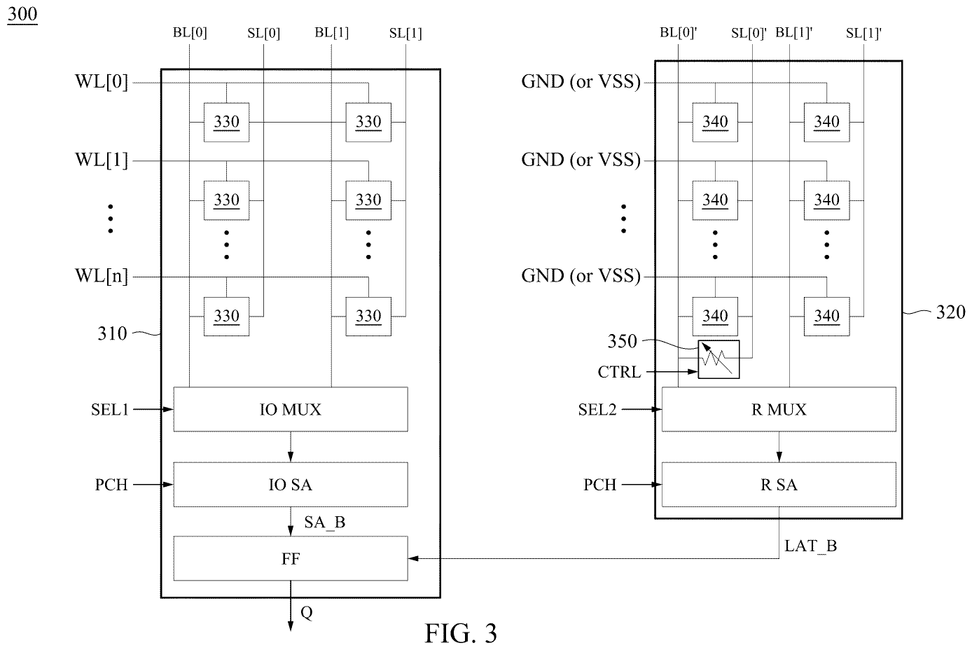

FIG. 3 is a schematic block/circuit diagram illustrating another exemplary system 300 in accordance with various embodiments of the present disclosure. As illustrated in FIG. 3, the example system 300 (e.g., system 100, 200) includes a memory device 310 and a memory device replica 320. The memory device 310 includes a plurality of memory cells 330, an input-output multiplexer (IO MUX), an input-output sense amplifier (IO SA), and a storage element (FF). The memory cells 330 store data therein during write operations and allow the stored data to be retrieved therefrom when a read operation is performed thereon. For example, the memory cells 330 are arranged in an array of rows and columns. The memory cells 330 in each row are connected to a respective word line (WL[0]-WL[n]). The memory cells 330 in each column are connected to a respective bit line (BL[0], BL[1]) and a respective source line (SL[0], SL[1]).

The input-output multiplexer (IO MUX) selects one of the memory cells 330 in response to a select signal (SEL1) (e.g., from an address decoder) and connects a bit line (BL[0], BL[1]) associated with the selected one of the memory cells 330 to the input-output sense amplifier (IO SA). During read operations, the input-output sense amplifier (IO SA) is initialized, e.g., to a VDD level, by a pre-charge signal (PCH) (e.g., from a signal generator) and generates a data output signal (SA_B) representing the bit stored in the selected one of the memory cells 330. The storage element (FF) receives the data output signal (SA_B) at a data input terminal thereof and, in response to a data latch signal (LAT_B) (e.g., from the memory device replica 320) at its clock input terminal, captures and outputs a bit (Q) that corresponds to the data output signal (SA_B) received thereby. In certain embodiments, the storage element (FF) includes a flip-flop (e.g., D-, JK-, SR-, or T-type), a shift register, another type of latch, or a combination thereof.

The memory device replica 320 mimics the behavior of the memory device 310 without storing actual data. For example, the memory device replica 320 includes a plurality of reference cells 340, a reference multiplexer (R MUX), a resistive element 350, and a reference sense amplifier (R SA). The reference cells 340 are arranged in an array of rows and columns. The reference cells 340 in each row are connected to a ground (or VSS) node. The reference cells 340 in each column are connected to a respective bit line (BL[0]′, BL[1]′) and a respective source line (SL[0]′, SL[1]′).

The reference multiplexer (R MUX) selects one of the reference cells 340 in response to a select signal (SEL2) (e.g., from an address decoder) and connects a bit line (BL[0]′, BL[1]′) associated with the selected one of the reference cells 340 to the reference sense amplifier (R SA). During read operations, the reference sense amplifier (R SA) is initialized, e.g., to a VDD level, by the pre-charge signal (PCH) and generates a data latch signal (LAT_B).

The resistive element 350 is connected between the junction of the reference cells 340 and the reference multiplexer (R MUX) and the ground (or VSS) node. In this exemplary embodiment, the resistive element 340 includes a potentiometer and receives a control signal (CTRL) (e.g., from a signal generator) that adjusts its resistance at a predetermined value. In an alternative embodiment, the resistive element 350 includes a resistor that has a fixed resistance value.

In an exemplary read operation, each multiplexer (IO MUX, R MUX) receives a respective select signal (SEL1, SEL2), establishing connections between a selected one of the memory cells 330 and the input-output sense amplifier (IO SA) and between a selected one of the reference cells 340 and the reference sense amplifier (R SA). Each sense amplifier (IO SA, R SA) is then initialized, e.g., to a VDD level, by a pre-charge signal (PCH) (e.g., from a signal generator). Next, each sense amplifier (IO SA, R SA) generates a respective signal (SA_B, LAT_B). Thereafter, the storage element (FF) receives the data output signal (SA_B) at a data input terminal thereof and, in response to the data latch signal (LAT_B) at its clock input terminal, captures and outputs a bit (Q) that corresponds to the data output signal (SA_B) received thereby.

Although the memory device 310 is exemplified with a pair memory cell 330 columns, it should be understood that, after reading this disclosure, the number of memory cell 330 columns may be decreased or increased as desired.

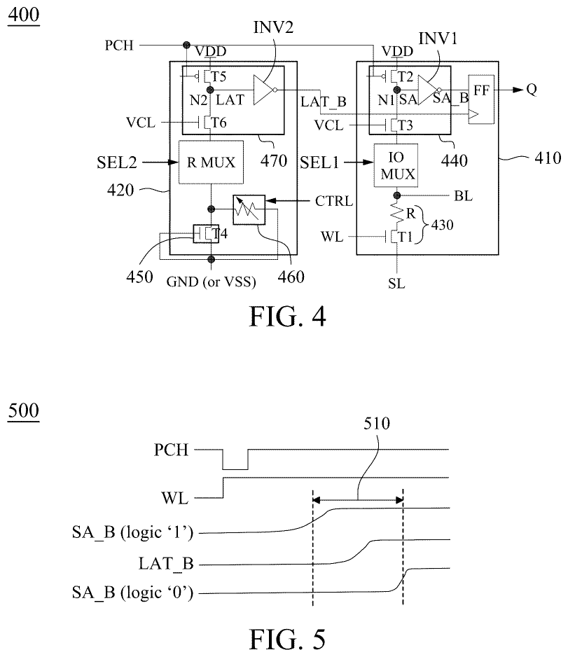

FIG. 4 is a schematic block/circuit diagram illustrating another exemplary system 400 in accordance with various embodiments of the present disclosure. As illustrated in FIG. 4, the example system 400 (e.g., system 100-300) includes a memory device 410 and a memory device replica 420. The memory device 410 includes a plurality of memory cells (e.g., memory cell 430), an input-output multiplexer (IO MUX), an input-output sense amplifier 440, and a storage element (FF). The memory cells 430 store data therein during write operations and allow the stored data to be retrieved therefrom when a read operation is performed thereon. In some embodiments, the memory cell 430 is a 1T1R (one transistor, one resistor) memory cell and includes a select transistor (T1) and a resistor (R). In such some embodiments, the resistor (R) is connected between a bit line (BL) and the first source/drain terminal of the select transistor (T1). The select transistor (T1) further has a second source/drain terminal connected to a source line (SL) and a gate terminal connected to a word line (WL). Alternative configurations for the memory cell 430 are contemplated in other embodiments.

The input-output multiplexer (IO MUX) selects one of the memory cells (e.g., memory cell 430) in response to a select signal (SEL1) (e.g., from an address decoder) and connects the bit line (BL) to the input-output sense amplifier 440. During read operations, the input-output sense amplifier 440 is initialized, e.g., to a VDD level, by a pre-charge signal (PCH) (e.g., from a signal generator) and generates a data output signal (SA_B) representing the bit stored in the memory cell 430. In some embodiments, the input-output sense amplifier 440 includes a pair of sense amplifier transistors (T2, T3) and a sense amplifier inverter (INV1).

The sense amplifier transistor (T2) includes a first source/drain terminal connected to a VDD node, a second source/drain terminal connected to a charge/discharge node (N1), and a gate terminal that receives the pre-charge signal (PCH). The sense amplifier transistor (T3) includes a first source/drain terminal connected to the charge/discharge node (N1), a second source/drain terminal connected to the input-output multiplexer (IO MUX), and a gate terminal that receives a voltage input signal (VCL) (e.g., from a signal generator). The sense amplifier inverter (INV1) is connected between the charge/discharge node (N1) and a data input terminal of the storage element (FF). Alternative configurations for the input-output sense amplifier (IO SA) are contemplated in other embodiments.

The storage element (FF) receives the data output signal (SA_B) at the data input terminal thereof and, in response to a data latch signal (LAT_B) (e.g., from the memory device replica 420) at its clock input terminal, captures and outputs a bit (Q) that corresponds to the data output signal (SA_B) received thereby. In certain embodiments, the storage element (FF) includes a flip-flop (e.g., D-, JK-, SR-, or T-type), a shift register, another type of latch, or a combination thereof.

The memory device replica 420 mimics the behavior of the memory device 410 without storing actual data. For example, the memory device replica 420 includes a plurality of reference cells (e.g., reference cell 450), a reference multiplexer (R-MUX), a resistive element 460, and a reference sense amplifier 470. In some embodiments, the reference cell 450 is a one transistor (1T) (i.e., no resistor) reference cell and includes a reference transistor (T4) that has a first source/drain terminal connected to the reference multiplexer (R MUX) and a second source/drain terminal and a gate terminal connected to each other and to a ground (or VSS) node. Alternative configurations for the reference cell 450 are contemplated in other embodiments.

The reference multiplexer (R MUX) selects one of the reference cells, e.g., reference cell 450, in response to a select signal (SEL2) (e.g., from an address decoder) and connects the reference cell 450 to the reference sense amplifier 470. During read operations, the reference sense amplifier 470 is initialized, e.g., to a VDD level, by the pre-charge signal (PCH) and generates a data latch signal (LAT_B). In some embodiments, the reference sense amplifier 470 includes a pair of sense amplifier transistors (T5, T6) and a sense amplifier inverter (INV2).

The sense amplifier transistor (T5) includes a first source/drain terminal connected to the VDD node, a second source/drain terminal connected to a charge/discharge node (N2), and a gate terminal that receives the pre-charge signal (PCH). The sense amplifier transistor (T6) includes a first source/drain terminal connected to the charge/discharge node (N2), a second source/drain terminal connected to the output of the reference multiplexer (R MUX), and a gate terminal that receives the voltage input signal (VCL). The sense amplifier inverter (INV2) is connected between the charge/discharge node (N2) and a clock input terminal of the storage element (FF). Alternative configurations for the reference sense amplifier 470 are contemplated in other embodiments.

The resistive element 460 is connected between the junction of the first source/drain terminal of the reference transistor (T4) and the reference multiplexer (R MUX) and the ground (or VSS) node. In this exemplary embodiment, the resistive element 460 includes a potentiometer and receives a control signal (CTRL) (e.g., from a signal generator) that adjusts its resistance at a predetermined value. In an alternative embodiment, the resistive element 460 includes a resistor that has a fixed resistance value.

In an exemplary read operation, each multiplexer (IO MUX, R MUX) receives a respective select signal (SEL1, SEL2), establishing connections between a selected one of the memory cells (e.g., memory cell 430) and the input-output sense amplifier 440 and between a selected one of the reference cells (e.g., reference cell 450) and the reference sense amplifier 470. Each charge/discharge node (N1, N2) is then initialized, e.g., to a VDD level, by a pre-charge signal (PCH). For example, FIG. 5 is a schematic timing diagram illustrating an exemplary sensing margin window 510 of a system (e.g., system 100-400), in accordance with various embodiments of the present disclosure. As illustrated in FIG. 5, when the pre-charge signal (PCH) transitions from high to low, the sense amplifier transistor (T2, T5) connects the charge/discharge node (N1, N2) to the VDD node, charging it to the VDD level. At substantially the same time, the word line (WL) signal transitions from low to high, activating the select transistor (T1) and connecting the resistor (R) to the ground (or VSS) node through the source line (SL). Next, each sense amplifier 440, 470 generates a respective signal (SA_B, LAT_B). Thereafter, the storage element (FF) receives the data output signal (SA_B) at its data input terminal and, in response to the data latch signal (LAT_B) at a clock input terminal thereof, captures and outputs a bit (Q) that corresponds to the data output signal (SA_B).

As shown in FIG. 5, when the memory cell 430 stores a logic ‘1’, the charge/discharge node (N1) remains at substantially the VDD level. As a result, the data output signal (SA_B) transitions from low to high earlier than the data latch signal (LAT_B) undergoes the same transitions. Conversely, when the memory cell 430 stores a logic ‘0’, the charge/discharge node (N1) is discharged from VDD to ground (or a VSS). As a result, the data output signal (SA_B) transitions from low to high later than the data latch signal (LAT_B) undergoes the same transition.

The sensing margin window 510 is defined by a time difference between the transition edge of the data output signal (SA_B) when the memory cell 430 stores a logic ‘0’ and when it stores a logic ‘1.’ This time difference ensures reliable data sensing and distinguishes between the two logic states.

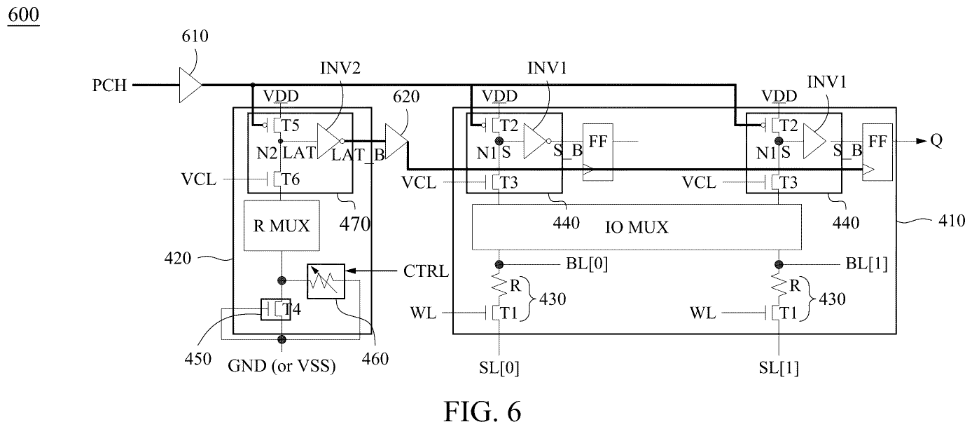

In certain embodiments, the position and/or size of the sensing margin window 510 may be adjusted to ensure that the transitions of the data output signal (SA_B) and the data latch signal (LAT_B) occur within the sensing margin window 510. For example, FIG. 6 is a schematic block/circuit diagram illustrating another exemplary system 600 in accordance with various embodiments of the present disclosure. As illustrated in FIG. 6, the example system 600 differs from the system 400 in that the system 600 further includes first and second buffer circuits 610, 620 that constitute a matching circuit that compensate timing variations between the pre-charge operations of the sense amplifier 440, 470, as well as the latch operations of the storage elements (FFs).

For example, the buffer circuit 610 receives the pre-charge signal (PCH) at its input terminal and provides a buffered version of the pre-charged signal (PCH) at an output terminal thereof connected to the gate terminal of the sense amplifier transistor (T2, T5). This buffering synchronizes the pre-charge operation across the sense amplifiers 440, 470, particularly for the input-output sense amplifiers 440 that are progressively farther from the reference sense amplifier 470, thereby mitigating layout-induced timing variations.

Similarly, the buffer circuit 620 is connected between the output terminal of the inverter (INV2) and the clock input terminals of the storage elements (FFs), receives the latch signal (LAT_B), and drives the storage elements (FFs). This driving synchronizes the latching operation across the storage elements (FFs), particularly for the storage elements (FFs) that are progressively farther from the reference sense amplifier 470, thereby further mitigating layout-induced timing variations. In some embodiments, each buffer circuit 610, 620 includes an even number of inverters connected in series. Alternative configurations for the matching circuit are contemplated in other embodiments.

By adjusting the drive strength and delay characteristics of the buffer circuits 610, 620, the position of the sensing margin window 510 can be tuned such that the transition of the data output signal (SA_B) occurs within the sensing margin window 510. This approach helps compensate for layout-dependent timing variations, particularly the near-to-far effect, where the input-output sense amplifiers 440 of the memory device 410 at different distances from the reference sense amplifier 470 experience different delays.

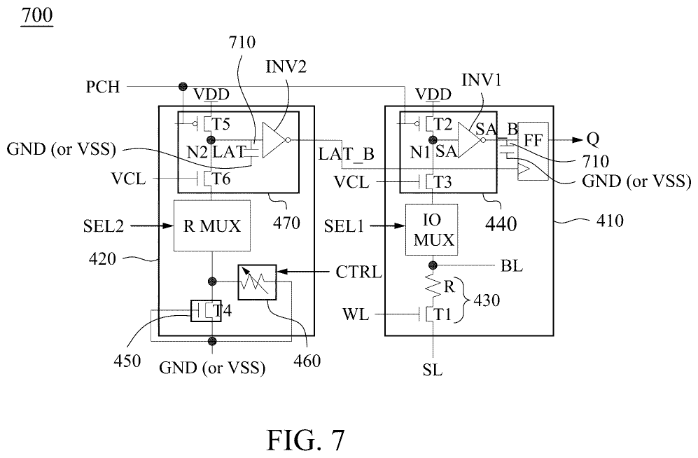

FIG. 7 is a schematic block/circuit diagram illustrating another exemplary system 700 in accordance with various embodiments of the present disclosure. As illustrated in FIG. 7, the example system 700 differs from the system 400 in that each sense amplifier 440, 470 of the system 700 further includes a capacitive element 710, 720. The capacitive elements 710, 720 constitute a discharge delaying circuit that slows down discharge rates of charge/discharge nodes (N1, N2). For example, the capacitive element 710 is connected across the charge/discharge node (N1) and a ground (or VSS) node, while the capacitive element 720 is connected across the charge/discharge node (N2) and the ground (or VSS) node. The construction as such slows down the discharge rate of the charge/discharge nodes (N1, N2), thereby increasing the duration of the sensing margin window 510. By adjusting the discharge characteristics of the charge/discharge node (N1, N2), the sensing margin window 510 can be widened, ensuring that the transition of the data output signal (SA_B) occurs within the sensing margin window 510.

In some embodiments, each capacitive element 710, 720 may be implemented using a metal-oxide-semiconductor (MOS) capacitor, a metal-oxide-metal (MOM) capacitor, a metal-insulator-metal (MIM) capacitor, other types of capacitors, or a combination thereof. Alternative configurations for the discharge delaying circuit are contemplated in other embodiments.

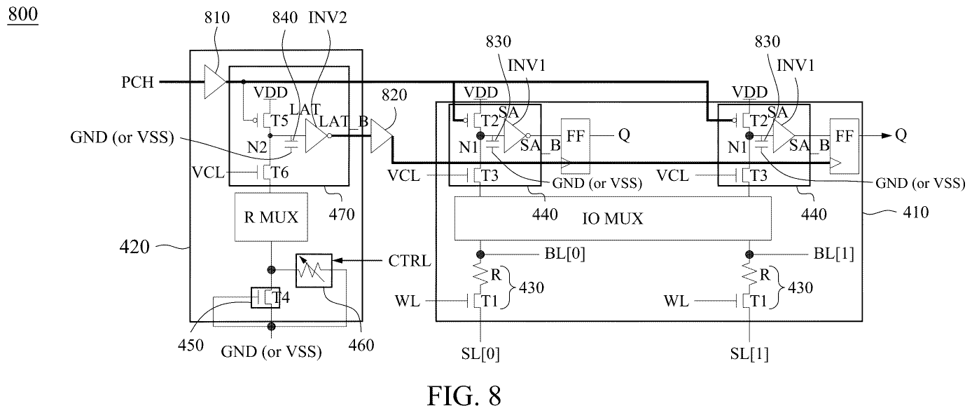

FIG. 8 is a schematic block/circuit diagram illustrating another exemplary system 800 in accordance with various embodiments of the present disclosure. As illustrated in FIG. 8, the example system 800 differs from the system 400 in that the system 800 further includes first and second buffer circuits 810, 820 that constitute a matching circuit that compensate timing variations between the pre-charge operations of the sense amplifier 440, 470, as well as the latch operations of the storage elements (FFs). For example, the buffer circuit 810 receives the pre-charge signal (PCH) at its input terminal and provides a buffered version of the pre-charged signal (PCH) at an output terminal thereof connected to the gate terminal of the sense amplifier transistor (T2, T5). This buffering synchronizes the pre-charge operation across the sense amplifiers 440, 470, particularly for the input-output sense amplifiers 440 that are progressively farther from the reference sense amplifier 470, thereby mitigating layout-induced timing variations.

Similarly, the buffer circuit 820 is connected between the output terminal of the inverter (INV2) and the clock input terminals of the storage elements, receives the latch signal (LAT_B), and drives the storage elements (FFs). This driving synchronizes the latching operation across the storage elements (FFs), particularly for the storage elements (FFs) that are progressively farther from the reference sense amplifier 470, thereby further mitigating layout-induced timing variations. In some embodiments, each buffer circuit 810, 820 includes an even number of inverters connected in series. Alternative configurations for the buffer circuits 810, 820 are contemplated in other embodiments.

By adjusting the drive strength and delay characteristics of the buffer circuits 810, 820, the position of the sensing margin window 510 can be tuned such that the transition of the data output signal (SA_B) occurs within the sensing margin window 510. This approach helps compensate for layout-dependent timing variations, particularly the near-to-far effect, where the input-output sense amplifier 440 at different distances from the reference sense amplifier 470 experience different delays.

Furthermore, each sense amplifier 440, 470 of the system 800 further includes a capacitive element 830, 840. The capacitive elements 830, 840 constitute a discharge delaying circuit that slows down discharge rates of charge/discharge nodes (N1, N2). For example, the capacitive element 830 is connected across the charge/discharge node (N1) and a ground (or VSS) node, while the capacitive element 840 is connected across the charge/discharge node (N2) and the ground (or VSS) node. The construction as such slows down the discharge rate of the charge/discharge nodes (N1, N2), thereby increasing the duration of the sensing margin window 510. By adjusting the discharge characteristics of the charge/discharge node (N1, N2), the sensing margin window 510 can be widened, ensuring that the transition of the data output signal (SA_B) occurs within the sensing margin window 510.

In some embodiments, each capacitive element 830, 840 may be implemented using a metal-oxide-semiconductor (MOS) capacitor, a metal-oxide-metal (MOM) capacitor, a metal-insulator-metal (MIM) capacitor, other types of capacitors, or a combination thereof.

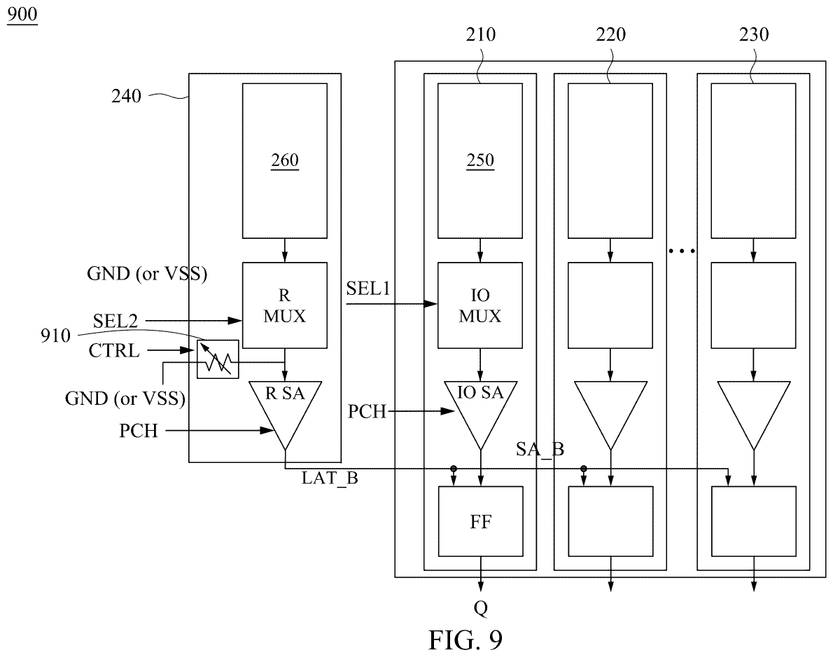

FIG. 9 is a schematic block/circuit diagram illustrating another exemplary system 900 in accordance with various embodiments of the present disclosure. As illustrated in FIG. 9, the example system 900 differs from the system 200 in that the resistive element 910 of the memory device replica 240 is connected between the junction of the reference multiplexer (R MUX) and the reference sense amplifier (R SA) and the ground (or VSS) node. The construction as such permits the reference multiplexer (R MUX) to better replicate the switching behavior of the input-output multiplexer (IO MUX) when selecting and connecting a memory cell to the input-output sense amplifier (IO SA). By mimicking the electrical characteristics of IO MUX more accurately, timing synchronization and signal consistency between the memory device and its replica are enchanced, leading to more stable and reliable read operations.

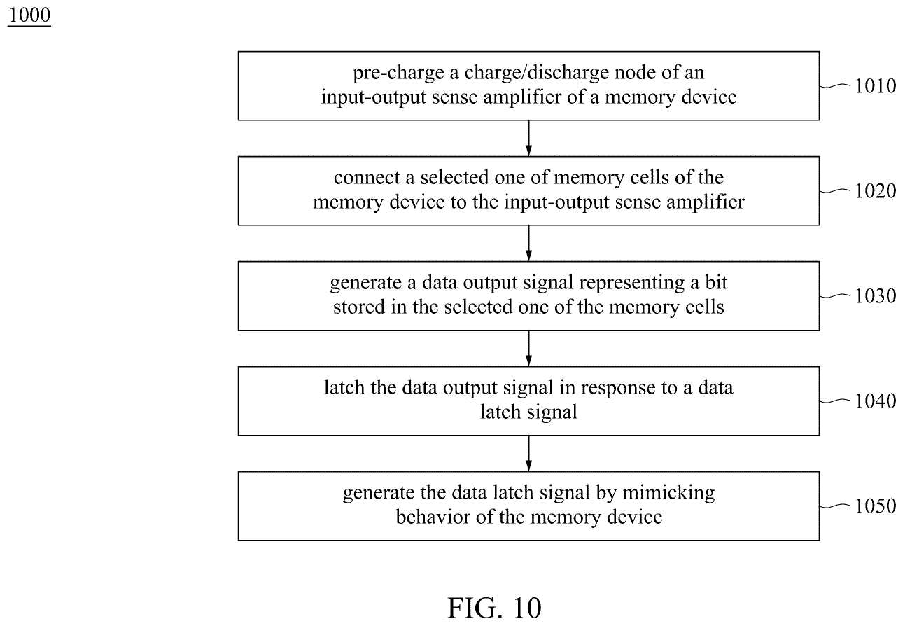

FIG. 10 is a flowchart of an exemplary method of performing a read operation on a memory device in accordance with various embodiments of the present disclosure. The example method 1000 will now be described with further reference to FIGS. 1-9 for ease of understanding. It is understood that the method 1000 is applicable to structures other than those of FIGS. 1-9. Further, it is understood that additional operations can be provided before, during, and after the method 1000, and some of the operations described below can be replaced or eliminated, in an alternative embodiment of the method 1000.

In operation 1010, a charge/discharge node (N1) of an input-output sense amplifier (IO SA) of a memory device 410 is pre-charged to a VDD level. At this time, one of the memory cells, e.g., memory cell 430, of the memory device 410 is selected and connected to a ground (or VSS) node. In operation 1020, the memory cell 430 is further connected to the input-output sense amplifier (IO SA), establishing a path for data retrieval. Next, in operation 1030, the input-output sense amplifier (IO SA) generates a data output signal (SA_B) representing a bit stored in the memory cell 430. Subsequently, in operation 1040, the storage element (FF) captures (or latches) the data output signal (SA_B) in response to a data latch signal (LAT_B) and outputs a bit (Q) that corresponds to the data output signal (SA_B). Thereafter, in operation 1050, the memory device replica 420 generates the data latch signal (LAT_B) by mimicking the behavior of the memory device 410, ensuring timing synchronization and stable data retrieval.

In an embodiment, a system comprises a memory device and a memory replica. The memory device includes a plurality of memory cell, an input-output multiplexer, an input-output sense amplifier, and a storage element. Each memory cell stores a bit of data. The input-output multiplexer is coupled to the memory cells and selects one of the memory cells in response to a select signal. The input-output sense amplifier generates a data output signal representing a bit stored in the selected one of the memory cells. The storage element latches the data output signal in response to a data latch signal and outputs a bit that corresponds to the data output signal. The memory device replica mimics the behavior of the memory device and generates the data latch signal.

In another embodiment, a memory device replica mimics the behavior of a memory device and comprises a plurality of reference cells, a reference multiplexer, a resistive element, a reference sense amplifier. The reference multiplexer is coupled to the reference cells and selects one of the reference cells in response to a select signal and connects the selected one of the reference cells to the reference sense amplifier. The resistive element is connected between the junction of the reference cells and the reference multiplexer and a ground or VSS node. The reference sense amplifier generates a data latch signal.

In another embodiment, a method of performing a read operation on a memory device comprises: pre-charging a charge/discharge node of an input-output sense amplifier of a memory device to a VDD level; selecting one of memory cells of the memory device; connecting the selected one of the memory cells to the input-output sense amplifier; generating, by the input-output sense amplifier, a data output signal representing a bit stored in the selected one of the memory cells; latching the data output signal in response to a data latch signal; and generating the data latch signal by mimicking behavior of the memory device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A system comprising:
a memory device including:
a plurality of memory cells, each configured to store a bit of data;
an input-output multiplexer coupled to the memory cells and configured to select one of the memory cells in response to a first select signal;
an input-output sense amplifier configured to generate a data output signal representing a bit stored in the selected one of the memory cells; and
a storage element configured to latch the data output signal in response to a data latch signal and to output a bit that corresponds to the data output signal; and
a memory device replica configured to mimic behavior of the memory device and to generate the data latch signal.

2. The system of claim 1, wherein the memory device replica includes:
a plurality of reference cells;
a reference multiplexer coupled to the reference cells and configured to select one of the reference cells in response to a second select signal and to connect the selected one of the reference cells to the reference sense amplifier;
a resistive element connected between the junction of the reference cells and the reference multiplexer and a ground or VSS node; and
the reference sense amplifier configured to generate the latch signal.

3. The system of claim 1, wherein the resistive element has a resistance that varies in response to control signal.

4. The system of claim 1, wherein the input-output sense amplifier includes:
a first transistor connected between a VDD node and a charge/discharge node;
a second transistor connected between the charge/discharge node and the input-output multiplexer; and
an inverter connected between the charge/discharge node and a data input terminal of the storage element.

5. The system of claim 1, wherein the reference sense amplifier includes:
a first transistor connected between a VDD node and a charge/discharge node;
a second transistor connected between the charge/discharge node and the reference multiplexer; and
an inverter connected between the charge/discharge node and a clock input terminal of the storage element.

6. The system of claim 1, further comprising a matching circuit configured to compensate timing variations between pre-charge operations of the input-output sense amplifier and the reference sense amplifier and latch operations of the storage element.

7. The system of claim 1, wherein the matching circuit includes:
a first buffer circuit configured to receive a pre-charge signal and to provide a buffered version of the pre-charge signal to the input-output sense amplifier and the reference sense amplifier; and
a second buffer circuit connected between the reference sense amplifier and the storage element.

8. The system of claim 1, further comprising discharge delaying circuit configured to slow down a discharge rate of the input-output sense amplifier and a discharge rate of the reference sense amplifier.

9. The system of claim 6, wherein the discharge delaying circuit includes a plurality of capacitors, each of which is connected to a charge/discharge node of a respective one of the input-output sense amplifier and the reference sense amplifier.

10. A memory device replica configured to mimic behavior of a memory device, the memory device replica comprising:
a plurality of reference cells;
a reference multiplexer coupled to the reference cells and configured to select one of the reference cells in response to a select signal and to connect the selected one of the reference cells to a reference sense amplifier;
a resistive element connected between the junction of the reference cells and the reference multiplexer and a ground or VSS node; and
the reference sense amplifier configured to generate a data latch signal.

11. The memory device replica of claim 10, wherein the resistive element has a resistance that varies in response to a control signal.

12. The memory device replica of claim 10, wherein:
the reference sense amplifier includes
a first transistor connected between a VDD node and a charge/discharge node;
a second transistor connected between the charge/discharge node and the reference multiplexer; and
an inverter connected to the charge/discharge node.

13. The memory device replica of claim 10, further comprising a matching circuit configured to compensate timing variations between a pre-charge operation of the reference sense amplifier and generation of the data latch signal by the reference sense amplifier.

14. The memory device replica of claim 13, wherein the matching circuit includes:
a first buffer circuit configured to receive a pre-charge signal and to provide a buffered version of the pre-charge signal to an input of the reference sense amplifier; and
a second buffer circuit connected to an output of the reference sense amplifier.

15. The memory device replica of claim 10, further comprising a discharge delay circuit coupled to the reference sense amplifier and configured to slow down discharge rate of the reference sense amplifier.

16. The memory device replica of claim 15, wherein the discharge delay circuit includes a capacitor connected to a charge/discharge node of the reference sense amplifier.

17. A method of performing a read operation on a memory device, the method comprising:
pre-charging a charge/discharge node of an input-output sense amplifier of a memory device to a VDD level;
selecting one of memory cells of the memory device;
connecting the selected one of the memory cells to the input-output sense amplifier;
generating, by the input-output sense amplifier, a data output signal representing a bit stored in the selected one of the memory cells;
latching the data output signal in response to a data latch signal; and
generating the data latch signal by mimicking behavior of the memory device.

18. The method of claim 17, wherein mimicking the behavior of the memory device includes:
pre-charging a charge/discharge node of a reference sense amplifier of a memory device replica to a VDD level;
selecting one of reference cells of the memory device replica;
connecting the selected one of the reference cells to the reference sense amplifier;
generating, by the input-output sense amplifier, the data latch signal.

19. The method of claim 18, wherein the pre-charging of the charge/discharge node of the input-output sense amplifier and the pre-charging of the charge/discharge node of the reference sense amplifier are substantially synchronized using a matching circuit.

20. The method of claim 18, further comprising delaying a discharge rate of the charge/discharge node of the input-output sense amplifier and a discharge rate of the charge/discharge node of the reference sense amplifier using a discharge delaying circuit.
